(19) United States
(12) Patent Application Publication
(10) Pub. No.: US 2003/0060037 A1
(43) Pub. Date: Mar. 27, 2003

(54) Method of manufacturing trench conductor line

(76) Inventor: Joseph Wu, Hsin-Pu Town (TW)

Correspondence Address: J.C. Patents, Inc., Suite 250, 4 Venture, Irvine, CA, 92618, US

(21) Appl. No.: 09/967,712

(22) Filed: Sep. 27, 2001

(51) Int. Cl. H01L 21/4763

(52) U.S. Cl. 438/637; 438/633; 438/634

(57) ABSTRACT

A method of manufacturing a trench conductor line. An etching stop layer, a dielectric layer and a polishing stop layer are sequentially formed over a substrate. The polishing stop layer and the dielectric layer are patterned to form a trench that exposes a portion of the etching stop layer. A conformal dielectric layer is formed over the polishing stop layer and the interior surface of the trench. A portion of the conformal dielectric layer is removed to expose the polishing stop layer and the etching stop layer within the trench. A conductive layer is formed over the polishing stop layer filling the trench. The conductive layer is planarized using the polishing stop layer as a polishing stop.

### BACKGROUND OF THE INVENTION

1. Field of Invention

The present invention relates to a method of manufacturing semiconductor devices. More particularly, the present invention relates to a method of manufacturing trench conductor line.

2. Description of Related Art

In general, a metallic interconnect is formed in three major steps. Photolithographic and etching processes are conducted to form a trench or a contact opening in a substrate. Metallic material is next deposited to fill the trench or the opening completely. Finally, a planarization operation such as a chemical-mechanical polishing is carried out to form a trench conductor line or a contact plug. However, due to rapid increase in the level of integration for integrated circuits, dimensions of each semiconductor device shrink. Thus, accurately controlling the critical dimension (CD) and depth of a trench line or a contact plug in increasingly difficulty In general, critical dimension of a trench line or a contact plug is mainly affected by CD limitation and process variation in the photolithographic and the etching step. On the other hand, depth of the trench line or the contact plug is largely affected by process variation in the chemical-mechanical polishing or etching.

FIG. 1 is a schematic cross-sectional view of the structure of a conventional trench conductor line. To form the trench conductor line in FIG. 1, dielectric material is deposited over a substrate 100 to form a dielectric layer 102. A trench is formed in the dielectric layer 102 by conducting a photolithographic and etching operation. Metallic material is deposited over the dielectric layer 102 and into the trench to form a metallic layer. Finally, the metallic layer is planarized to form a trench conductor line 104 within the trench by chemical-mechanical polishing.

Proper control of critical dimension W and depth D of the trench conductor line 104 are very important. However, critical dimension W of the conductor line 104 is likely to be affected by critical dimension limitation and variation in the photolithographic or the etching processes and depth D of the conductor line is likely to be affected by variation in the etching or the chemical-mechanical polishing process. Thus, the conventional method not only provides little control over the critical dimension and depth of a conductor line, but also provides little control over any width variation from the top section to the bottom section of the conductor line.

Similarly, to form a dual damascene structure, a dual damascene opening is formed in a dielectric layer by conducting a photolithographic and etching operation. Metallic material is deposited over the dielectric layer and into the dual damascene opening to form a metallic layer and then the metallic layer is planarized to form a dual damascene structure within the dielectric layer by chemical-mechanical polishing. Hence, the conventional method of forming a dual damascene structure faces the same types of problems for controlling the critical dimension and depth as the method of forming a trench conductor line. Furthermore, if the dual damascene structure has a large aspect ratio, additional manufacturing problems may be encountered.

### SUMMARY OF THE INVENTION

Accordingly, one object of the present invention is to provide a method of manufacturing a trench conductor line having a tighter control over its critical dimension and depth.

A second object of this invention is to provide a method of manufacturing a dual damascene structure having a tighter control over its critical dimension and depth

A third object of this invention is to provide a method of manufacturing a metallic interconnect whose component conductive line and dual damascene structure have a higher degree of dimensional uniformity.

To achieve these and other advantages and in accordance with the purpose of the invention, as embodied and broadly described herein, the invention provides a method of manufacturing a trench conductor line. An etching stop layer, a dielectric layer and a polishing stop layer are sequentially formed over a substrate. The polishing stop layer and the dielectric layer are patterned to form a trench that exposes the etching stop layer. A conformal dielectric layer is formed over the polishing stop layer and the interior surface of the trench. A portion of the conformal dielectric layer is removed to expose the polishing stop layer and the etching stop layer within the trench. A conductive layer is formed over the polishing stop layer filling the trench. The conductive layer is planarized using the polishing stop layer as a polishing stop to form a trench conductor line.

This invention also provides an alternative method of manufacturing a trench conductor line. An etching stop layer, a dielectric layer and a polishing stop layer are sequentially formed over a substrate. The polishing stop layer and the dielectric layer are patterned to form a trench that exposes the etching stop layer. A conductive layer is formed over the polishing stop layer filling the trench. The conductive layer is planarized using the polishing stop layer as a polishing stop to form a trench conductor line.

This invention also provides a method of manufacturing a dual damascene structure. A first conductive structure and a second conductive structure are formed over a substrate. A first dielectric layer is formed over the substrate covering the first conductive structure and the second conductive structure. An etching stop layer, a second dielectric layer and a polishing stop layer are formed over the first dielectric layer sequentially. The polishing stop layer and the second dielectric layer are patterned to form a first trench and a second trench, wherein the first trench and the second trench expose the etching stop layer. The etching stop layer and the first dielectric layer are patterned to form a first via opening and a second via opening. The first via opening exposes the first conductive structure The second via opening exposes a portion of the substrate and is formed on one side of the second conductive structure. A first dual damascene opening is composed of the first trench and the first via opening, and a second dual damascene opening is composed of the second trench and the second via opening. A conformal dielectric layer is formed over the polishing stop layer and the interior surface of the first dual damascene opening and the second dual damascene opening. A portion of the conformal dielectric layer is removed to expose the polishing stop layer, the first conductive structure in the first dual damascene opening and the substrate in the second dual damascene opening. A conductive layer is formed over the polishing stop layer filling the first dual damascene opening and the second dual damascene opening. The conductive layer is planarized until the polishing stop layer is exposed to form a first dual damascene structure and a second dual damascene structure.

This invention also provides a method of manufacturing a dual damascene structure. A first conductive structure and a second conductive structure are formed over a substrate. A first dielectric layer is formed over the substrate covering the first conductive structure and the second conductive structure. An etching stop layer, a second dielectric layer and a polishing stop layer are formed over the first dielectric layer sequentially. The polishing stop layer, the second dielectric layer, the etching stop layer and the first dielectric layer are patterned to form a first via opening and a second via opening The first via opening exposes the first conductive structure. The second via opening exposes a portion of the substrate and is formed on one side of the second conductive structure. The etching stop layer and the first dielectric layer are patterned to form a first trench and a second trench, wherein the first trench and the second trench expose the etching stop layer. A first dual damascene opening is composed of the first trench and the first via opening, and a second dual damascene opening is composed of the second trench and the second via opening. A conformal dielectric layer is formed over the polishing stop layer and the interior surface of the first dual damascene opening and the second dual damascene opening. A portion of the conformal dielectric layer is removed to expose the polishing stop layer, the first conductive structure in the first dual damascene opening and the substrate in the second dual damascene opening. A conductive layer is formed over the polishing stop layer filling the first dual damascene opening and the second dual damascene opening. The conductive layer is planarized until the polishing stop layer is exposed to form a first dual damascene structure and a second dual damascene structure

This invention employs an etching stop layer and a polishing stop layer to control depth of a trench conductor line and a trench conductor line of a dual damascene structure accurately. This invention also utilizes a conformal dielectric layer formed over the interior surface of a trench or a dual damascene opening for precise control of the critical dimension of the trench conductor line and the dual damascene structure. In addition, the trench conductor line and the dual damascene structure formed by the method of this invention has a better dimensional uniformity than a conventional method.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of the structure of a conventional trench conductor line;

FIGS. 2A through 2E are schematic cross-sectional views showing the progression of steps for producing a trench conductor line according to a first embodiment of this invention;

FIG. 3 is a schematic cross-sectional view showing the structure formed by an alternative method of forming a trench conductor line according to the first embodiment of this invention; and

FIGS. 4A through 4E are schematic cross-sectional views showing the progression of steps for producing a dual damascene structure according to a second embodiment of this invention.

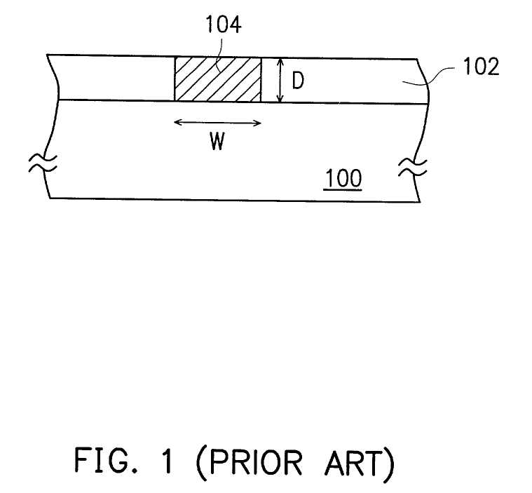

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

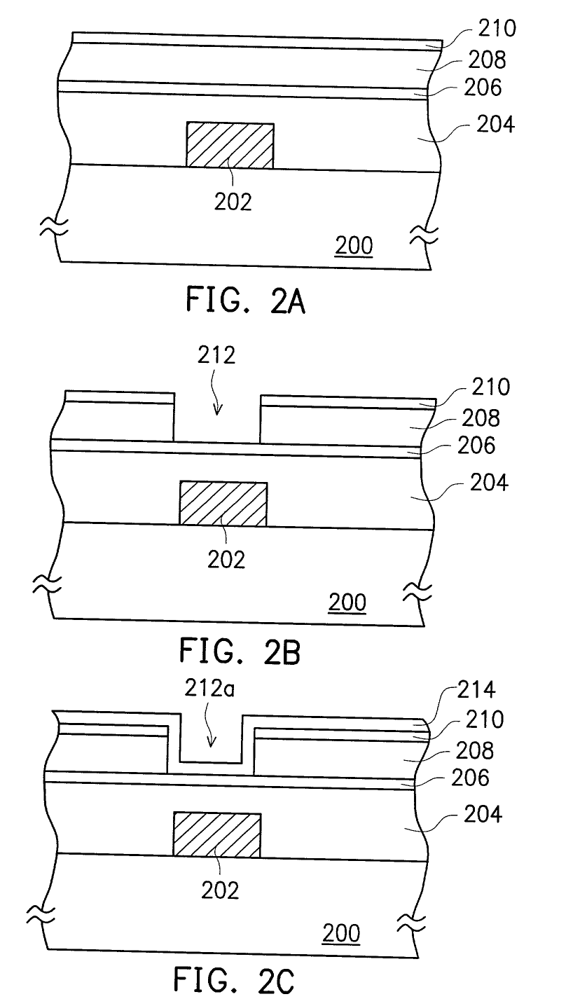

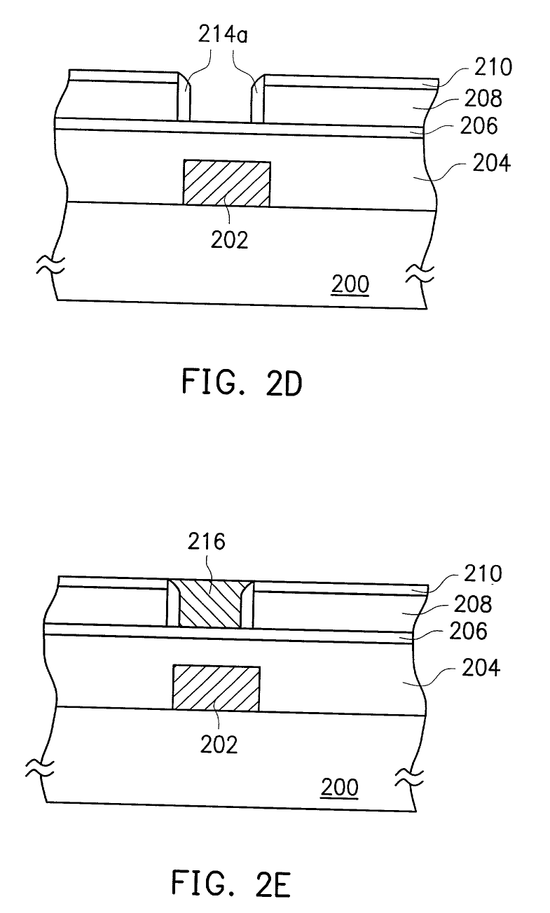

FIGS. 2A through 2E are schematic cross-sectional views showing the progression of steps for producing a trench conductor line according to a first embodiment of this invention. As shown in FIG. 2A, a substrate 200 having a conductor structure 202 therein is provided. The conductive structure 202, for example, can be a gate structure. A first dielectric layer 204 is formed over the substrate 200 covering the first conductive structure 202. The first dielectric layer 204, for example, can be a silicon oxide layer. An etching stop layer 206 is formed over the first dielectric layer 204. The etching stop layer 206, for example, can be a silicon nitride layer having a thickness of between 20 Å to 50 Å. A second dielectric layer 208 is formed over the etching stop layer 206. The second dielectric layer 208, for example, can be a silicon oxide layer having a thickness that depends on the conductive line such as 1000 Å to 3000 Å. A polishing stop layer 210 is formed over the second dielectric layer 208. The polishing stop layer 210, for example, can be a silicon nitride layer having a thickness between 20 Å to 50 Å.

As shown in FIG. 2B, the polishing stop layer 210 and the second dielectric layer 208 are patterned to form a trench 212 that exposes a portion of the etching stop layer 206. Since the etching stop layer 206 has an etching rate lower than the second dielectric layer 208, the patterning of the polishing stop layer 210 and the second dielectric layer 208 abruptly stops at the etching stop layer 206. Hence, depth of the trench 212 can be precisely controlled.

As shown in FIG. 2C, a conformal dielectric layer 214 is formed over the polishing stop layer 210 and the interior surface of the trench 212. The conformal dielectric layer 214, for example, can be a silicon nitride layer or a silicon oxynitride layer. Thickness of the conformal dielectric layer 214 is adjusted according to the width of the trench 212. In general, a thicker conformal dielectric layer 214 is formed in a wider trench so that width of the trench 212a is able to meet the critical dimension requirement. Similarly, a thinner conformal dielectric layer 214 is formed in a narrower trench so that with of the trench 212a is able to meet the critical dimension requirement.

As shown in FIG. 2D, a portion of the conformal dielectric layer 214 is removed so that the polishing stop layer 210 and the etching stop layer 206 inside the trench 212a are exposed. Ultimately, only a pair of conformal dielectric layers 214a remain attached to the sidewalls of the trench 212a. The conformal dielectric layer 214 is removed, for example, by dry etching.

As shown in FIG. 2E, a conductive material is deposited into the trench 212a to form a trench conductor line 216. The conductive material can be tungsten, for example. The trench conductor line 216 is formed, for example, by depositing conductive material over the polishing stop layer 210 and into the trench 212a and chemical-mechanical polishing the conductive layer using the polishing stop layer 210 as a polishing stop. Since the polishing stop layer 210 has a lower polishing rate than the conductive layer, conductive material outside the trench 212a is removed. Hence, thickness of the conductive line 216 can be precisely controlled.

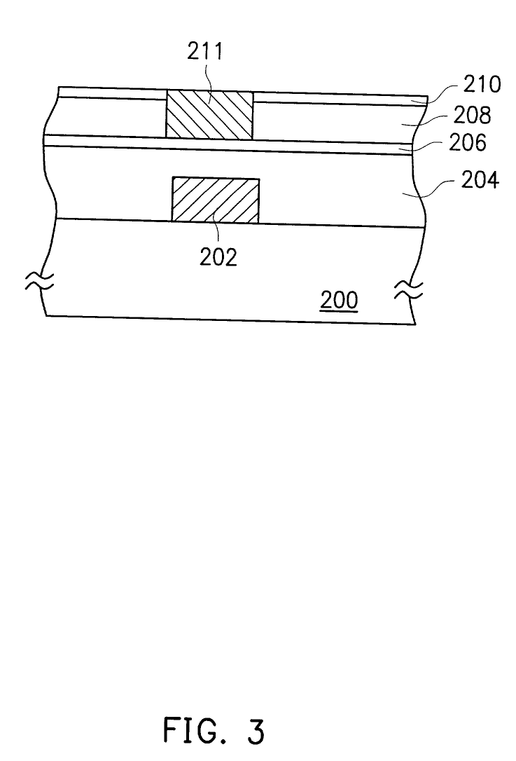

FIG. 3 is a schematic cross-sectional view showing the structure formed by an alternative method of forming a trench conductor line according to the first embodiment of this invention. In this method, after forming the trench 212 as shown in FIG. 2B, conductive material is directly deposited into the trench 212 (as shown in FIG. 3) to form a trench conductor line 211. The conductive material can be tungsten, for example. The trench conductor line 211 is formed, for example, by depositing conductive material over the polishing stop layer 210 and into the trench 212a and chemical-mechanical polishing the conductive layer using the polishing stop layer 210 as a polishing stop.

In the first embodiment, the etching stop layer 206 is used to control depth of the trench 212 accurately. Furthermore, the polishing stop layer 210 and the etching stop layer 206 are used together to control depth of the conductor line 211 precisely. In addition, this invention permits the formation of a wider trench 212. Width of the trench 212 is subsequently adjusted using the conformal dielectric layer 214 to meet tight critical dimension requirement. Therefore, the trench conductor line 216 can have a high degree of dimensional uniformity. In other words, width of the trench conductor line 216 varies very little from its bottom section to its top section.

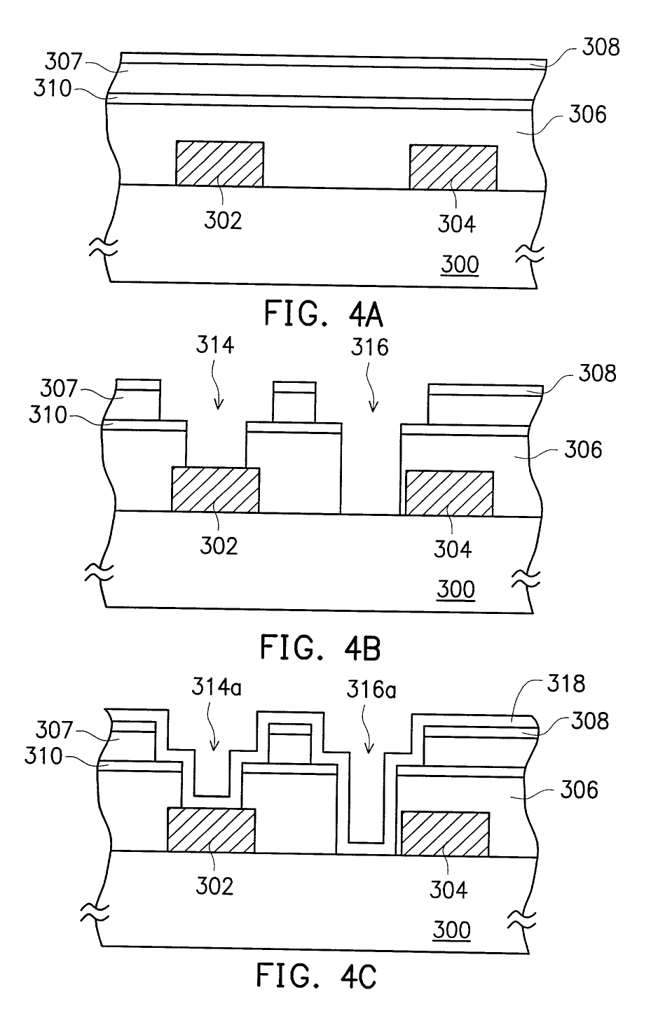

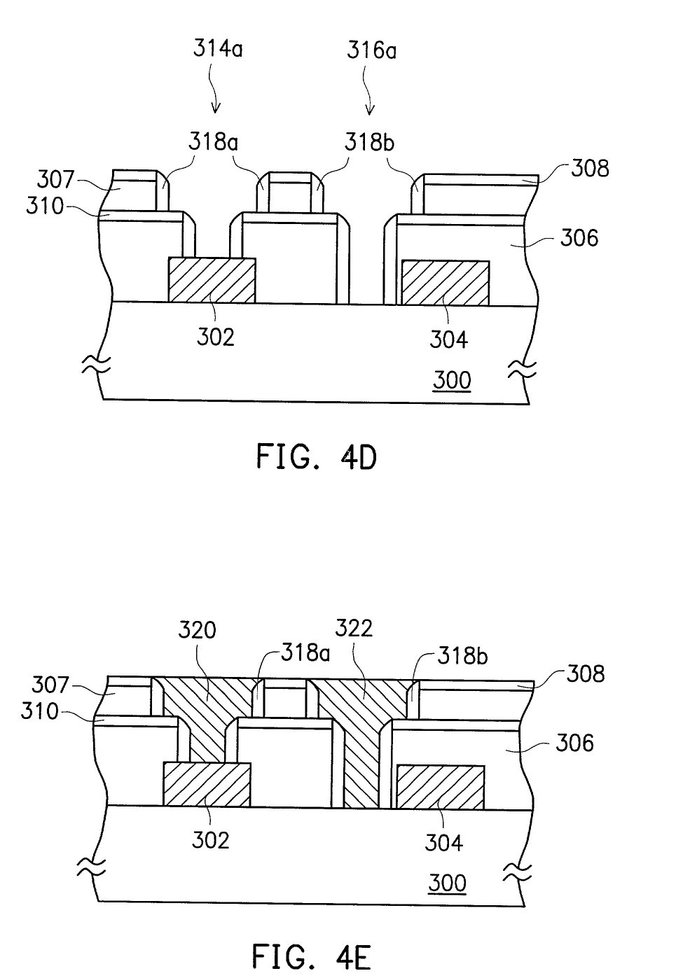

FIGS. 4A through 4E are schematic cross-sectional views showing the progression of steps for producing a dual damascene structure according to a second embodiment of this invention. As shown in FIG. 4A, a first conductive structure 302 and a second conductor structure 304 are formed on a substrate 300. The conductive structures 302 and 304 can be gate structures, for example. A dielectric layer 306 is formed over the substrate 300 covering both conductive structures 302 and 304. An etching stop layer 310, a dielectric layer 307 and a polishing stop layer 308 are formed over the dielectric layer 306 sequentially. The dielectric layers 306, 307 can be a silicon oxide layer, for example. The etching stop layer 310 can be, for example, a silicon nitride layer having a thickness between 20 Å to 50 Å. And the polishing stop layer 308 can be, for example, a silicon nitride layer having a thickness between 20 Å to 50 Å.

As shown in FIG. 4B, the dielectric layer 306, the etching stop layer 310, the dielectric layer 307 and the polishing stop layer 308 are patterned to form a first dual damascene opening 314 and a second dual damascene opening 316. The first dual damascene opening 314 exposes the first conductive structure 302. The second dual damascene opening 316 exposes a portion of the substrate 300 and is formed on one side of the second conductive structure 304.

One method for forming the first dual damascene opening 314 and the second dual damascene opening 316, for example, is that the polishing stop layer 308 and the dielectric layer 307 are patterned to form a first trench and a second trench which expose the etching stop layer 310 firstly. Then the etching stop layer 310 and the dielectric layer 306 are patterned to form a first via opening and a second via opening. The first dual damascene opening 314 is composed of the first trench and the first via opening, and the second dual damascene opening 316 is composed of the second trench and the second via opening.

Another method for forming the first dual damascene opening 314 and the second dual damascene opening 316, for example, is that the polishing stop layer 308, the dielectric layer 307, the etching stop layer 310 and the dielectric layer 306 are patterned to form a first via opening and a second via opening firstly. Then the polishing stop layer 308 and the dielectric layer 307 are patterned to form a first trench and a second trench, wherein the first trench and the second trench expose the etching stop layer 310. The first dual damascene opening 314 is composed of the first trench and the first via opening, and the second dual damascene opening 316 is composed of the second trench and the second via opening.

As shown in FIG. 4C, a conformal dielectric layer 318 is formed over the polishing stop layer 308 and the interior surface of the first dual damascene opening 314 and the second dual damascene opening 316. The conformal dielectric layer 318 can be made, for example, from silicon nitride or silicon oxynitride. Thickness of the conformal dielectric layer 318 depends on the width of the first dual damascene opening 314 and the second dual damascene opening 316. For example, if the first dual damascene opening 314 and the second dual damascene opening 316 are relatively wide, a thicker conformal dielectric layer 318 is usually formed so that critical dimension requirement for both the first dual damascene opening 314a and the second dual damascene opening 316a are met. On the other hand, if the first dual damascene opening 314 and the second dual damascene opening 316 are relatively narrow, a thinner conformal dielectric layer 318 is usually formed so that critical dimension requirement for both the first dual damascene opening 314a and the second dual damascene opening 316a are met.

As shown in FIG. 4D, a portion of the conformal dielectric layer 318 is removed exposing the polishing stop layer 308, a portion of the first conductive structure 302 inside the first dual damascene opening 3 14a and a portion of the substrate 300 inside the second dual damascene opening 316a. Ultimately, only the conformal dielectric layers 318a and 318b are still attached to the sidewalls of the first dual damascene opening 314a and the second dual damascene opening 316a. The conformal dielectric layer 318 is removed, for example, by dry etching.

As shown in FIG. 4E, a conductive material is deposited into the first dual damascene opening 314a to form a first dual damascene structure 320 and into the second dual damascene opening 316a to form a second dual damascene structure 322 respectively. The conductive material for forming the dual damascene structure includes tungsten, for example. The dual damascene structures 320 and 322 are formed, for example, by depositing conductive material over the polishing stop layer 308 and into the first dual damascene opening 314a and the second dual damascene opening 316a, and chemical-mechanical polishing the conductive layer using the polishing stop layer 308 as a polishing stop. Since the polishing stop layer 308 has a polishing rate lower than the conductive layer, excess conductive material above the polishing stop layer 308 is removed after chemical-mechanical polishing. Hence, depth of both dual damascene structures 320 and 322 can be precisely controlled.

In the second embodiment, a conformal dielectric layer 318b is formed on the sidewalls of the dual damascene structure 322. The conformal dielectric layer 318b is capable of preventing any short circuit between the dual damascene structures 322 and the second conductive structure 304.

In conclusion, the advantages of this invention includes:

1. An etching stop layer and a polishing stop layer are employed to control the depth of a trench conductor line and a trench conductor line of a dual damascene structure accurately.

2. A conformal dielectric layer formed over the interior surface of a trench or a dual damascene opening is utilized to control precisely the critical dimension of the trench conductor line and the dual damascene structure.

3. The trench conductor line and the dual damascene structure formed by the method of this invention has a higher degree of dimensional uniformity than a conventional method.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a trench conductor line, comprising the steps of
providing a substrate having an etching stop layer thereon;
forming a dielectric layer over the etching stop layer;
forming a polishing stop layer over the dielectric layer;
patterning the polishing stop layer and the dielectric layer to form a trench that exposes a portion of the etching stop layer;
forming a conformal dielectric layer over the polishing stop layer and the interior of the trench;
removing a portion of the conformal dielectric layer to expose the polishing stop layer and a portion of the etching stop layer within the trench,
forming a conductive layer over the polishing stop layer and filling the trench; and
planarizing the conductive layer using the polishing stop layer as a polishing stop.

2. The method of claim 1, wherein the etching stop layer has an etching rate lower than the dielectric layer.

3. The method of claim 1, wherein material forming the etching stop layer includes silicon nitride.

4. The method of claim 1, wherein material forming the dielectric layer includes silicon oxide.

5. The method of claim 1, wherein the polishing stop layer has a polishing rate lower than the conductive layer.

6. The method of claim 1, wherein material forming the conductive layer includes tungsten.

7. The method of claim 1, wherein material forming the polishing stop layer includes silicon nitride.

8. The method of claim 1, wherein material forming the conformal dielectric layer is selected from a group consisting of silicon nitride and silicon oxynitride.

9. A method of manufacturing a trench conductor line, comprising the steps of:
providing a trench having an etching stop layer thereon;
forming a dielectric layer over the etching stop layer;
forming a polishing stop layer over the dielectric layer;
patterning the polishing stop layer and the dielectric layer to form trench that exposes a portion of the etching stop layer;
forming a conductive layer over the polishing stop layer and filling the trench; and
planarizing the conductive layer using the polishing stop layer as a polishing stop.

10. The method of claim 9, wherein the etching stop layer has an etching rate lower than the second dielectric layer.

11. The method of claim 9, wherein material forming the etching stop layer includes silicon nitride.

12. The method of claim 9, wherein material forming the second dielectric layer includes silicon oxide.

13. The method of claim 9, wherein the polishing stop layer has a polishing rate lower than the conductive layer.

14. The method of claim 9, wherein material forming the polishing stop layer includes silicon nitride.

15. A method of manufacturing a dual damascene structure, comprising the steps of:
providing a substrate having a first conductive structure and a second conductive structure thereon;
forming a first dielectric layer over the substrate that covers the first conductive structures and the second conductive structures;
forming a etching stop layer, a second dielectric layer and a polishing stop layer over the first dielectric layer sequentially;
patterning the polishing stop layer, the second dielectric layer, the etching stop layer and the first dielectric layer to form a first via opening and a second via opening, wherein the first via opening exposes a portion of the first conductive structure and the second via opening exposes a portion of the substrate and is on one side of the second conductive structure;
patterning the polishing stop layer and the second dielectric layer to form a first trench and a second trench, wherein the first trench and the second trench expose the etching stop layer, and a first dual damascene opening is composed of the first trench and the first via opening and a second dual damascene opening is composed of the second trench and the second via opening;
forming a conformal dielectric layer over the polishing stop layer and the interior surface of the first and the second dual damascene opening;
removing a portion of the conformal dielectric layer to expose the polishing stop layer, the first conductive structure inside the first dual damascene opening and a portion of the substrate inside the second dual damascene opening;
forming a conductive layer over the polishing stop layer and filling the first dual damascene opening and the second dual damascene opening; and
planarizing the conductive layer using the polishing stop layer as a polishing stop.

16. The method of claim 15, wherein the etching stop layer has an etching rate lower than the second dielectric layer.

17. The method of claim 15, wherein material forming the etching stop layer includes silicon nitride.

18. The method of claim 15, wherein material forming the second dielectric layer includes silicon oxide.

19. The method of claim 15, wherein the polishing stop layer has a polishing rate lower than the conductive layer.

20. The method of claim 15, wherein material forming the polishing stop layer includes silicon nitride.
